(19) United States
(12) Patent Application Publication
(10) Pub. No.: US 2016/0309098 A1
(43) Pub. Date: Oct. 20, 2016

(54) IMAGE CAPTURING DEVICE WITH AN IMAGE SENSOR AND A THERMAL INFRARED SENSOR AS WELL AS MOTOR VEHICLE WITH AN IMAGE CAPTURING DEVICE

(71) Applicant: CONNAUGHT ELECTRONICS LTD, Galway (IE)

(72) Inventors: Ian Barry Montandon, Workingham (GB); Patrick Eoghan Denny, Roscam (IE)

(73) Assignee: Connaught Electronics Ltd., Galway (IE)

(21) Appl. No.: 15/102,909

(22) PCT Filed: Oct. 28, 2014
(86) PCT No.: PCT/EP2014/073059

§ 371 Date: Jun. 9, 2016

(30) Foreign Application Priority Data
Dec. 12, 2013 (DE) 10 2013 021 519.6

(51) Int. Cl. H04N 5/33; B60W 30/14; H01L 27/148; B60R 11/04; H04N 9/04; H01L 27/146

(52) U.S. Cl. CPC H04N 5/332; H04N 9/045; H01L 27/1465; H01L 27/14634; H01L 27/14636; H01L 27/14645; H01L 27/14627; H01L 27/14806; H01L 27/14881; H01L 27/14618; B60R 11/04; B60W 30/14; B60R 2300/106

(57) ABSTRACT

The invention relates to an image capturing device (1) for a motor vehicle, including an image sensor (2) formed for capturing light in the visible spectral range and for providing photographic image data, and including a thermal infrared sensor (3) formed for capturing thermal radiation in the far infrared range and for providing thermographic image data, wherein the image sensor (2) and the thermal infrared sensor (3) are integrated in a common chip package (4).

The invention relates to an image capturing device for a motor vehicle, including an image sensor and a thermal infrared sensor. The image sensor is formed for capturing light in the visible spectral range and provides photographic image data. The infrared sensor in turn is formed for capturing thermal radiation in the far infrared range as well as for providing thermographic image data. In addition, the invention relates to a motor vehicle with such an image capturing device.

Front cameras for motor vehicles are already prior art. Such front cameras are usually employed in advanced driver assistance systems for various applications, such as for example for LDW (Lane Departure Warning) applications, for ACC (Adaptive Cruise Control) applications, for AEC (Automatic Emergency Control) applications and the like. Usually, front cameras include a color-sensitive image sensor (for example CMOS), which is able to capture light in the visible spectral range and thus provide photographic image data. Therein, the front cameras are typically disposed behind the windshield such that the visible light is captured through the windshield. Usually, the front cameras have a VGA resolution or a resolution of 1.3 megapixels.

Moreover, night vision cameras are also employed in motor vehicles, which have a thermal infrared sensor being able to detect thermal radiation in the far infrared range. Since the material of the windshield attenuates the infrared radiation, such night vision cameras are placed outside of the interior of the vehicle, for example on the front bumper or the like. Such infrared sensors typically have a QVGA resolution. Due to the employed MEMS sensors and the required vacuum isolation, the night vision cameras are relatively expensive compared to front cameras with a conventional CMOS image sensor.

A motor vehicle with a front camera including a conventional image sensor as well as with a night vision camera including a thermal infrared sensor is for example known from the document U.S. Pat. No. 7,786,898. The front camera is disposed in the interior of the motor vehicle on the windshield, while the night vision camera is disposed outside of the interior.

DE 10 2013 000 260 A1 describes two different image sensors, which are sensitive to different spectral ranges. These image sensors are disposed adjacent to each other.

If a conventional front camera as well as a night vision camera is employed, thus, the photographic images as well as the thermographic images can be combined with each other. Thus, images can be provided, which are based both on the thermographic image data and the photographic image data. However, the employment of two separate cameras has proven relatively disadvantageous since two different components have to be mounted in the motor vehicle. On the one hand, this increases the manufacturing cost of the motor vehicle; on the other hand, two separate cameras also require relatively much installation space, which is available in motor vehicles only in limited manner. However, the crucial disadvantage is in that the possibility of providing combined images such as for example stereo images is restricted due to the different arrangement of the cameras—outside of the interior on the one hand and in the interior on the other hand.

It is an object of the invention to provide an image capturing device of the initially mentioned kind improved with respect to the prior art as well as a motor vehicle with such an image capturing device.

According to the invention, this object is solved by an image capturing device as well as by a motor vehicle having the features according to the respective independent claims. Advantageous implementations of the invention are the subject matter of the dependent claims, of the description and of the figures.

An image capturing device according to the invention is conceived for installation on and/or in a motor vehicle and includes an image sensor as well as a thermal infrared sensor. The image sensor is formed for capturing light in the visible (for the human) spectral range and for providing photographic image data. The thermal infrared sensor is a sensor different from the image sensor, which is formed for capturing thermal radiation in the far infrared range (in particular at a wavelength greater than 3 μm) and for providing thermographic image data. According to the invention, the image sensor and the thermal infrared sensor are integrated in a common chip package.

According to the invention, the image sensor and the thermal infrared sensor are thus collectively encased with the aid of the chip package. Thus, the image capturing device is provided in the form of a single component with a chip package, from which electrical connecting elements protrude, via which the image data can be output and via which the integral image capturing device can for example be coupled to a circuit board. The image sensor and the thermal infrared sensor are thus disposed adjacent and in a known distance to each other, whereby combined images can also be provided without much effort, which are based both on the thermographic image data and the photographic image data. For example, it is thus possible to provide stereo images. In addition, two separate cameras do not have to be mounted on the motor vehicle any more, but rather only a single component has to be mounted now, whereby the valuable installation space on the one hand and also the cost on the other hand can be saved. The image capturing device can for example be mounted on the vehicle front, for example on the front bumper.

Preferably, a CSP (Chip Scale Package) or a TSV (Through-Silicon Via) package is employed as the common chip package. Thus, standardized package types can be used, which else are also used for semiconductor circuits.

It proves particularly advantageous if the image sensor and the thermal infrared sensor are disposed on a common substrate within the chip package. This further improves the integration density of the image capturing device. Thus, the image capturing device can be particularly compactly provided. The arrangement of the two sensors on a common substrate additionally has the advantage that the two image sensors are therefore disposed very close to each other and hereby undesired optical effects can be avoided.

Preferably, the image sensor and the thermal infrared sensor have respective capturing sides, via which the visible light and the thermal radiation, respectively, are captured. This means that the image sensor has a capturing side, via which the visible light is captured, as well as the thermal infrared sensor also has a capturing side, via which the thermal radiation is captured. Therein, the image sensor and the thermal infrared sensor are disposed on the common substrate such that the capturing sides face the substrate. Therein, the common substrate can be formed of a material, which is transparent to both the visible light and the thermal radiation. The material can include glass and/or ceramic. The capture of the visible light and of the thermal radiation is thus effected through the common substrate. Such an arrangement of the sensors has the advantage that micro lenses can for example be provided on the opposite side of the substrate.

Preferably, electrical contact pads are provided on the common substrate, to which the image sensor and the thermal infrared sensor are electrically coupled for transmitting the respective image data. These contact pads can be coupled to respective connecting elements, which protrude from the chip package and serve for connecting the image capturing device to a separate circuit board.

Preferably, at least one micro lens, in particular a WLO (Wafer Level Optics), for the image sensor and/or the thermal infrared sensor is integrated in the chip package. Such micro lenses are considerably more compact than conventional lenses such that the height of the image capturing device can be reduced compared to conventional cameras. Thus, further optic elements separate from the image capturing device do not have to be employed.

Therein, it is preferably provided that at least one micro lens, in particular a WLO, is respectively integrated in the chip package both for the image sensor and for the thermal infrared sensor. Therein, the micro lenses can be disposed on that side of the common substrate, which faces away from the image sensor and the infrared sensor.

The image sensor can for example be a CMOS sensor or else a CCD sensor.

In addition, the invention relates to a motor vehicle, in particular a passenger car, with an image capturing device according to the invention.

Further features of the invention are apparent from the claims, the figures and the description of figures. All of the features and feature combinations mentioned above in the description as well as the features and feature combinations mentioned below in the description of figures and/or shown in the figures alone are usable not only in the respectively specified combination, but also in other combinations or else alone.

Now, the invention is explained in more detail based on a preferred embodiment as well as with reference to the attached drawings.

There show:

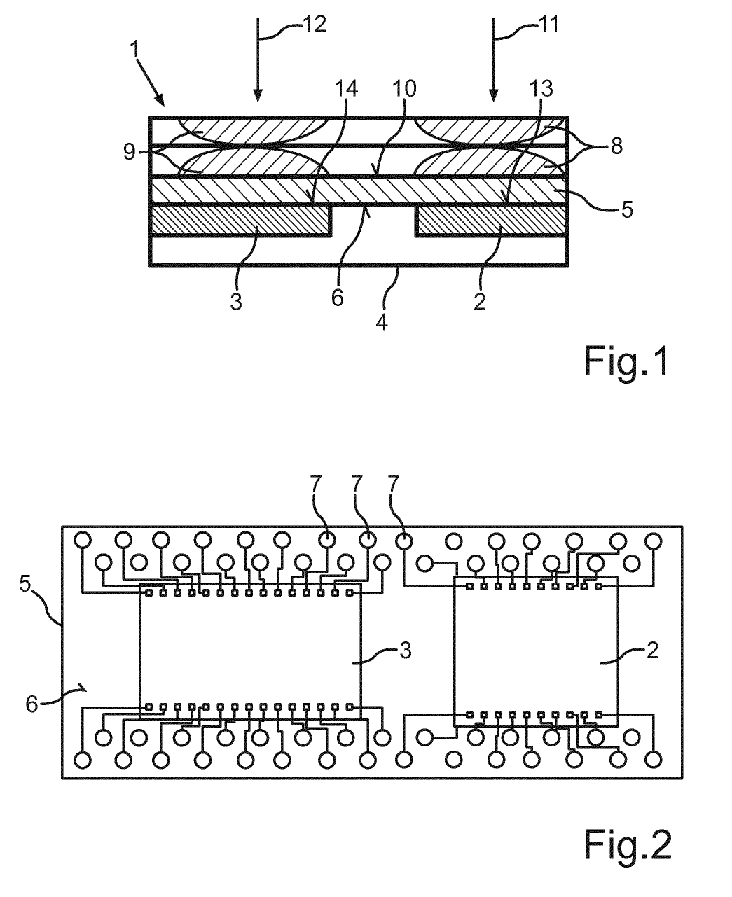

FIG. 1 in schematic illustration a sectional view through an image capturing device according to an embodiment of the invention; and

FIG. 2 in schematic illustration a top view of a substrate with an image sensor and a thermal infrared sensor.

An image capturing device 1 illustrated in FIG. 1 is formed for employment in a motor vehicle. The image capturing device 1 can for example be mounted on a vehicle front, for example on the front bumper. The image capturing device 1 includes an image sensor 2 as well as a thermal infrared sensor 3, which are accommodated in a common chip package 4. The image sensor 2 is for example a CMOS sensor or a CCD sensor. The image sensor 2 can capture light in the visible spectral range (with a wavelength of for example 300 nm to 900 nm) and provide photographic image data depending on the captured visible light. In comparison, the thermal infrared sensor 3 is formed to capture thermal radiation in the far infrared range (with a wavelength of for example 3 μm to 15 μm) and to provide thermographic image data depending on the captured thermal radiation.

In the embodiment, the common chip package 4 is a CSP (Chip Scale Package) or a TSV (Through-Silicon Via) package. A common substrate 5 is provided for the image sensor 2 and the infrared sensor 3, which is transparent to both the visible light and the infrared radiation. The common substrate 5 presents a carrier for the image sensor 2 and the infrared sensor 3. Ceramic and/or glass can be used as the material of the substrate 5.

The image sensor 2 and the infrared sensor 3 are disposed on a backside 6 of the substrate 5. The image sensor 2 and the infrared sensor 3 have respective capturing sides 13, 14, via which the visible light and the thermal radiation, respectively, are captured. The capturing sides 13, 14 face the substrate 5 and in particular abut the backside 6.

A top view of the backside 6 and the image sensor 2 as well as the infrared sensor 3 is shown in FIG. 2 in schematic manner and not to scale according to an embodiment of the invention. As is apparent from FIG. 2, electrical contact pads 7 can be disposed on the substrate 5, to which the image sensor 2 on the one hand and also the thermal infrared sensor 3 on the other hand are electrically coupled. Connecting elements (not illustrated) can also be coupled to these contact pads 7, which protrude from the chip package 4 and via which the image data can be output.

With reference again to FIG. 1, micro lenses 8, 9 both for the image sensor 2 and for the infrared sensor 3 are integrated in the chip package 4. The micro lenses 8, 9 are WLO (Wafer Level Optics) elements. These micro lenses 8, 9 are disposed on a front side 10 of the substrate 5, which faces away from the sensors 2, 3. The visible light is captured via the capturing side 13 of the image sensor 2 through the material of the substrate 5 as well as through the micro lenses 8, wherein the direction of the incident light is denoted by 11 in FIG. 1. Correspondingly, the infrared sensor 3 also captures the thermal radiation via the capturing side 14 and through the material of the substrate 5 as well as through the micro lenses 9, wherein the direction of incidence of the thermal radiation is denoted by 12.

In FIG. 1, two layers of micro lenses 8, 9 are illustrated. However, the number of the layers can be arbitrary and be in a range of values from 1 to for example 4. Therein, the micro lenses 8 are formed of a material, which is especially suitable for the visible light. Correspondingly, the micro lenses 9 are of a material specially conceived for the thermal radiation.

1. An image capturing device for a motor vehicle, comprising:
an image sensor, which is formed for capturing light in the visible spectral range and for providing photographic image data; and
a thermal infrared sensor, which is formed for capturing thermal radiation in the far infrared range and for providing thermographic image data,
wherein the image sensor and the thermal infrared sensor are integrated in a common chip package .

2. The image capturing device according to claim 1, wherein the common chip package is a CSP or a TSV package.

3. The image capturing device according to claim 1, wherein the image sensor and the thermal infrared sensor are disposed on a common substrate within the chip package.

4. The image capturing device according to claim 3, wherein the image sensor and the thermal infrared sensor have respective capturing sides, via which the visible light and the thermal radiation are captured, respectively, and which face the common substrate, wherein the common substrate is formed of a material, which is transparent to both the visible light and the thermal radiation.

5. The image capturing device according to claim 3, wherein electrical contact pads are provided on the common substrate, to which the image sensor and the thermal infrared sensor are electrically coupled for transmitting the respective image data.

6. The image capturing device according to claim 1, wherein at least one micro lens for the image sensor and/or the thermal infrared sensor is integrated in the chip package.

7. The image capturing device according to claim 6, wherein both for the image sensor and for the thermal infrared sensor, at least one micro lens is respectively integrated in the chip package.

8. The image capturing device according to claim 1, wherein the image sensor is formed as a CMOS image sensor or CCD image sensor.

9. A motor vehicle with an image capturing device according to claim 1.

10. The image capturing device according to claim 6, wherein the at least one micro lens is a wafer level optics (WLO).
